(19) United States
(12) Patent Application Publication
(10) Pub. No.: US 2025/0140654 A1
(43) Pub. Date: May 1, 2025

(54) PACKAGE CARRIER HAVING LARGE CORNER LEADS WITH LEAD TIP INSPECTION FEATURE

(71) Applicant: Infineon Technologies AG, Neubiberg (DE)

(72) Inventors: Jing GUO, Sauerlach (DE); Maofen ZHANG, München (DE)

(73) Assignee: Infineon Technologies AG, Neubiberg (DE)

(21) Appl. No.: 18/899,260

(22) Filed: Sep. 27, 2024

(30) Foreign Application Priority Data
Oct. 25, 2023 (DE) 10 2023 129 401.6

(51) Int. Cl. H01L 23/495; H01L 21/66; H01L 23/00

(52) U.S. Cl. CPC H01L 23/49548; H01L 22/32; H01L 23/4952; H01L 24/32; H01L 2224/32245; H01L 2924/182

(57) ABSTRACT

A carrier for a leadless package is disclosed. In one example, the carrier comprises a component mounting structure for mounting an electronic component thereon, and a plurality of leads arranged around at least part of the component mounting structure, wherein corner leads of said leads are located closer to at least one corner of said component mounting structure than intermediate leads of said leads located farther away from said at least one corner than said corner leads, wherein said corner leads have a larger width along a respective edge of the component mounting structure compared with a smaller width of said intermediate leads, and wherein at least said corner leads comprise a lead tip inspection feature.

### CROSS-REFERENCE TO RELATED APPLICATION

This Utility patent application claims priority to German Patent Application No. 10 2023 129 401.6 filed Oct. 25, 2023, which is incorporated herein by reference.

### BACKGROUND

### Technical Field

Various embodiments relate generally to a carrier for a leadless package, a leadless package, and an electronic device.

### Description of the Related Art

A package may be denoted as encapsulated electronic component with electrical connects extending out of the encapsulant. For example, packages may be connected to an electronic periphery, for instance mounted on a printed circuit board, and may be connected via connectors to a larger system.

For testing manufactured packages after such a package is installed on a mounting base such as a printed circuit board (PCB), the packages on the mounting base may be subjected to repeated temperature cycling to simulate thermal load exerted during operation of the package. A temperature cycling test may be conducted under conditions of predefined maximum and minimum temperatures and in air-to-air environment.

### SUMMARY

There may be a need for a package with thermo-mechanical robustness, in particular concerning thermal cycling.

According to an exemplary embodiment, a carrier for a leadless package is provided, wherein the carrier comprises a component mounting structure for mounting an electronic component thereon, and a plurality of leads arranged around at least part of the component mounting structure, wherein corner leads of said leads are located closer to at least one corner of said component mounting structure than intermediate leads of said leads located farther away from said at least one corner than said corner leads, wherein said corner leads have a larger width along a respective edge of the component mounting structure compared with a smaller width of said intermediate leads, and wherein at least said corner leads comprise a lead tip inspection feature.

According to another exemplary embodiment, a leadless package is provided which comprises a carrier having the above mentioned features, an electronic component mounted on the component mounting structure, and an encapsulant encapsulating at least part of the electronic component, at least part of the component mounting structure, and only part of the leads.

According to another exemplary embodiment, an electronic device is provided which comprises a mounting base (for example a printed circuit board), and a package having the above mentioned features mounted on the mounting base.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates different views of a carrier for a leadless package according to an exemplary embodiment.

FIG. 2 illustrates a plan view of a carrier for a leadless package according to an exemplary embodiment.

FIG. 3 illustrates a cross-sectional view of an electronic device according to an exemplary embodiment.

FIG. 4 illustrates a plan view of the electronic device according to FIG. 3.

FIG. 5 illustrates a result of a simulation showing an improved second level solder joint thermal cycle on board (TCoB) test performance of a package according to an exemplary embodiment compared with other approaches.

FIG. 6 illustrates a cross-sectional view of part of a leadless package showing a lead tip inspection feature according to an exemplary embodiment.

FIG. 7 illustrates a cross-sectional view of part of a leadless package showing a lead tip inspection feature according to another exemplary embodiment.

FIG. 8 illustrates different views of an electronic device according to an exemplary embodiment.

FIG. 9 illustrates three-dimensional views of leads having lead tip inspection features according to exemplary embodiments.

FIG. 10 illustrates different views of a process of manufacturing leads with lead tip inspection feature according to an exemplary embodiment.

FIG. 11 illustrates different views of a process of manufacturing leads with lead tip inspection feature according to another exemplary embodiment.

FIG. 12 illustrates a plan view of a carrier with lead tip inspection feature for a leadless package according to an exemplary embodiment.

FIG. 13 illustrates a plan view of a carrier with lead tip inspection feature for a leadless package according to another exemplary embodiment.

FIG. 14 illustrates a result of a simulation showing an improved second level solder joint thermal cycle on board (TCoB) test performance of packages according to exemplary embodiments.

### DETAILED DESCRIPTION

There may be a need for a package with thermo-mechanical robustness, in particular concerning thermal cycling.

According to an exemplary embodiment, a carrier for a leadless package is provided, wherein the carrier comprises a component mounting structure for mounting an electronic component thereon, and a plurality of leads arranged around at least part of the component mounting structure, wherein corner leads of said leads are located closer to at least one corner of said component mounting structure than intermediate leads of said leads located farther away from said at least one corner than said corner leads, wherein said corner leads have a larger width along a respective edge of the component mounting structure compared with a smaller width of said intermediate leads, and wherein at least said corner leads comprise a lead tip inspection feature.

According to another exemplary embodiment, a leadless package is provided which comprises a carrier having the above mentioned features, an electronic component mounted on the component mounting structure, and an encapsulant encapsulating at least part of the electronic component, at least part of the component mounting structure, and only part of the leads.

According to another exemplary embodiment, an electronic device is provided which comprises a mounting base (for example a printed circuit board), and a package having the above mentioned features mounted on the mounting base.

According to an exemplary embodiment, a carrier for a leadless package is provided which has excellent properties in terms of thermo-mechanical reliability during thermal cycling tests and/or more generally under thermal load. Such a leadless package may comprise a component mounting structure, such as a die pad, on which an electronic component, such as a semiconductor chip, may be mounted. Partially or entirely around said component mounting structure, a plurality of leads may be arranged which may be used for electrically connecting the electronic component to an electronic periphery when the electronic component is mounted on the component mounting structure and encapsulated by an encapsulant, such as a mold compound. It has been found that solder fatigue failure due to thermal loading occurs in many cases first at so-called corner leads, i.e., a subgroup of said leads which are located adjacent to corners of the for example polygonal component mounting structure. Advantageously, two measures are taken according to exemplary embodiments for improving the second level solder joint thermal cycle on board (TCoB) test performance or second level reliability of a package using the above-mentioned carrier. The first measure is to extend the width selectively of the corner pads, whereas the width of the remaining intermediate leads may be kept small, i.e. smaller than the adapted width of the corner pads. Intermediate leads may be leads arranged along an edge of the component mounting structure, for example between corner leads which may be arranged closest to different corners of the component mounting structure. It has been found that by extending the width of the corner leads, second level solder fatigue failure at corner leads may be strongly suppressed. At the same time, keeping the intermediate leads smaller than the spatially extended corner leads may ensure that no or at least no significant decrease of the pitch of the lead arrangement occurs, which ensures compliance with specifications of many package applications. Keeping the width of the intermediate leads as it is may keep the package size at a small form factor. If the intermediate leads would also be enlarged, there might be a need to change the pitch to a smaller value in order to be still able to put all the leads in a defined package. The second measure, which has been found to synergistically cooperate with the first measure for achieving excellent second level solder joint thermal cycle on board (TCoB) test performance, is to provide at least part of external sidewalls at least of the corner leads with a lead tip inspection (LTI) feature. Descriptively speaking, such an LTI feature of exterior sidewalls or sidewall portions of the corner leads may ensure that a solder fillet wets the LTI feature at the sidewalls. This may allow a reliable and simple optical inspection of a successful soldering process, and may also contribute significantly to an enhancement of the second level solder reliability robustness of the package as a whole. Simulations have provided indications that the combination of the two mentioned measures may provide an improvement of the thermal cycling failure robustness. Thus, the described carrier configuration may lead to a package having excellent second level solder joint thermal cycle on board (TCoB) test performance, in particular during thermal cycling tests. At the same time, the two mentioned measures may be implemented very easily in a manufacturing process and do not involve significant extra effort.

### DESCRIPTION OF FURTHER EXEMPLARY EMBODIMENTS

In the following, further exemplary embodiments of the carrier, the package, and the electronic device will be explained.

In the context of the present application, the term “carrier” may particularly denote a support structure which serves as a mechanical support for one or more electronic components to be mounted thereon. In other words, the carrier may fulfil a mechanical support function. Additionally, or alternatively, a carrier may also fulfill an electrical connection function. For this purpose, at least part of the carrier may be electrically conductive. A carrier may comprise or consist of a single part, multiple parts joined via encapsulation or other package components, or a subassembly of carrier sections. A carrier may also contribute to heat removal and heat spreading from the electronic component out of the package for promoting thermal dissipation. A metallic carrier, for instance comprising or consisting of copper and/or aluminum, may have a high thermal conductivity and may thus be excellent in terms of its heat removal capability. A sufficiently high heat capacity of a carrier may be advantageous as well. For example, a carrier may form part of a lead frame structure.

In the context of the present application, the term “package” may particularly denote an electronic member which may comprise one or more electronic components mounted on one or more carriers, said at least one carrier to comprise or consist out of a single part, multiple parts joined via encapsulation or other package components, or a subassembly of carriers. Said constituents of the package may be encapsulated at least partially by an encapsulant, wherein leads may be partially exposed.

In the context of the present application, the term “leadless package” may particularly denote a package having a configuration in which no elongate lead legs extend out of the encapsulant. In contrast to this, the leads of a leadless package may be fully encapsulated by encapsulant material with the exception of metallic surfaces of leads which are in flush or substantially in flush with the exterior encapsulant surfaces and do not significantly protrude beyond it. More precisely, leads of a leadless package may be exposed beyond the encapsulant only at a bottom main surface of the encapsulant and at sidewalls thereof, but no circumferentially exposed lead legs extend out of the encapsulant.

In the context of the present application, the term “component mounting structure” may particularly denote an at least partially electrically conductive structure functioning as a support for an electronic component to be mounted thereon. For example, the electronic component may be mounted on the component mounting structure by soldering, sintering or gluing. When the component mounting structure is at least partially electrically conductive, it may also provide an electric coupling function of the electronic component with an electronic periphery. For example, the component mounting structure may be a die pad for carrying a semiconductor die, in particular when the carrier is embodied as a patterned metal plate or leadframe structure. For example, the component mounting structure may have a polygonal shape, in particular a rectangular shape. Optionally, it is possible that one or more corners of the polygonal component mounting structure are rounded, provided with an extension, etc.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a bare die or may be already packaged or encapsulated. Semiconductor chips implemented according to exemplary embodiments may be formed in particular in silicon technology, gallium nitride technology, silicon carbide technology, gallium oxide technology, etc. Particularly preferred may be one or more power semiconductor chips, chips manufactured from a wide bandgap semiconductor, etc.

In the context of the present application, the term “leads” may particularly denote electrically conductive structures which may be electrically coupled with the electronic component and/or the component mounting structure for enabling exterior access to the electronic component when the latter is encapsulated.

In the context of the present application, the term “corner leads” may particularly denote a subgroup of leads arranged around at least part of a perimeter of a component mounting structure and being arranged directly adjacent or closest to a corner of the component mounting structure. The corner leads may be arranged closer to a respectively closest corner of the component mounting structure than the intermediate leads.

In the context of the present application, the term “intermediate leads” may particularly denote a subgroup of leads which are not the closest leads to the corners of the component mounting structure, but are further remote from corners of the component mounting structure than respective corner leads.

In the context of the present application, the term “lead tip inspection feature” may particularly denote any provision on and/or in a sidewall surface of a lead which allows or promotes wetting of solder material thereon when a corresponding sidewall portion with lead tip inspection feature is exposed beyond an encapsulant after encapsulation. For example, a lead tip inspection feature may comprise a plating structure on the sidewall or a portion thereof, wherein the material of the plating structure can be appropriate to allow wetting of solder material thereon. For example, such a plating structure may comprise tin. Additionally or alternatively, a lead tip inspection feature may comprise at least one recess in the sidewall increasing the surface area which may also promote wetting by melted solder material. The provision of a plating structure in a sidewall recess may be a preferred option of a lead tip inspection feature.

In the context of the present application, the term “encapsulant” may particularly denote an electrically insulating and preferably thermally conductive material surrounding at least part of an electronic component and at least part of a carrier, and also part of one or more leads. For instance, the encapsulant may be a mold compound and may be manufactured for example by transfer molding. It may also be possible that the encapsulant is of a gel-type, which may be used for encapsulating by potting.

In the context of the present application, the term “electronic device” may particularly denote a device with electronic functionality and which may comprise a package with one or more electronic components mounted on an encapsulated carrier with exposed leads. The electronic device may have a mounting base carrying said package.

In the context of the present application, the term “mounting base” may particularly denote a structure being electrically and/or mechanically connected with the package. For instance, such a mounting base may be a printed circuit board (PCB). The package may be surface mounted on the mounting base.

While corner leads may be located closer to at least one corner of said component mounting structure than intermediate leads, a pitch may remain constant.

In an embodiment, said lead tip inspection feature comprises a plating structure configured for being wettable by a solder structure and being formed on at least part of a respective sidewall of a respective one of at least said corner leads. In particular, a respective corner lead may have a vertical or slanted sidewall. The sidewall may be straight or curved, for instance in a convex or concave manner. A plating structure, for example a plating layer, may be formed on part of the sidewall or on the entire sidewall. If the plating structure is formed on only a part of the sidewall of a respective corner lead, it may be formed on a bottom-sided portion thereof. For example, 40% to 60% of the sidewall surface may be covered by the plating structure. The plating structure may be made of a material which has the property to allow wetting of molten solder material thereon. For example, the plating layer may comprise tin for this purpose. A sidewall or sidewall portion of a corner lead may be covered by solder material, for instance a solder fillet, when a package formed on the basis of such a carrier is solder-connected with a mounting base beneath it. It has been found that such a solder fillet covering at least part of an exposed sidewall of a corner lead or pad significantly improves the robustness of a package against failure when carrying out a thermal cycling test or more generally when exposing the package to thermal stress.

In an embodiment, said lead tip inspection feature comprises a recess (for example at least partially covered by a plating structure) formed in at least part of a respective sidewall of a respective one of at least said corner leads. Such a recess in a sidewall of the respective corner lead may for example be an opening, an indentation, an undercut, a blind hole, a cavity. It is also possible to form a plurality of recesses in the sidewall. To put it shortly, the recess may increase the surface area of the sidewall and may therefore additionally promote wetting by solder material when soldering a carrier-based package on a mounting base. Advantageously, a part of the sidewall of the corner lead with recess may be covered with a plating structure being wettable by solder material. In particular, the plating structure may be formed in the recess. It is also possible that the plating structure is formed in the recess and in another part of the sidewall apart from the recess. Furthermore, it is possible to have a plurality of recesses in the sidewall. It has been found that a recess-based lead tip inspection feature of a corner lead may significantly improve the reliability of a corresponding package when undergoing thermal cycling tests. When the recess is covered by a plating structure, a full plating LTI feature may be provided which may ensure a pronounced and reliable coverage by a solder fillet.

In an embodiment, said recess is formed in a corner region of the respective corner lead (for example as a dimple or a step), which corner region includes a bottom portion of the sidewall and a connected portion of a bottom wall of the respective corner lead. It has also been found that forming a recess at a bottom end of the sidewall extending into a corner of the corner lead and extending up to its bottom surface provides also an LTI feature which significantly improves the robustness of the package against thermal load or stress. Preferably, such a recess is coated with a plating structure, such as a plating layer, for example comprising tin, which improves wettability by molten solder material. Apart from the corner-sided recess, also a part of the sidewall of the corner lead may be coated with a plating structure for further improving wettability.

In an embodiment, said recess is formed in a central portion of the sidewall of the respective corner lead (for example as a dimple or a step). More specifically, one or more recesses may be formed in the middle of a sidewall of a corner lead for improving wettability by molten solder material. Preferably, a recess in the sidewall may be combined with sidewall plating, wherein the plating material may be selected to be capable of wetting molten solder material.

A skilled person will understand that the mentioned embodiments of recesses in a sidewall of a corner lead are only exemplary, and that many modifications are possible. Moreover, additional or alternative other LTI features may be created at the sidewall of a corner lead for improving the robustness against thermal load, in particular thermal cycling load.

In an embodiment, each of the leads comprises a plating structure configured for being wettable by a solder structure and being formed at least on at least part of a bottom wall of the respective lead. A plating structure at an exposed bottom side of the leads, preferably of corner leads and intermediate leads, may be preferred. This may render such surfaces wettable by molten solder material and may thereby promote a strong connection between a bottom side of the leads exposed beyond an encapsulant of a package on the one hand and a mounting base, such as a PCB, on the other hand. Hence, when creating a solder connection between package and mounting base, the bottom-sided plating structure on the leads may promote a reliable solder connection. Advantageously, a common plating structure may cover the bottom side and the at least part of a sidewall of a lead, in particular of a corner lead. This may simultaneously ensure a reliable solder connection and a high robustness against thermal load. Furthermore, such a common plating structure may be formed in one common plating process, and thus highly efficiently.

In an embodiment, the intermediate leads comprise a lead tip inspection (LTI) feature. Thus, not only the corner leads, but also the intermediate leads may optionally be provided with a lead tip inspection feature. Although generally intermediate leads are less prone to failure than corner leads in the event of thermal load (for instance applied during executing a thermal cycling process), forming an LTI feature on the sidewall of the intermediate leads may further improve their thermal robustness. Embodiments for such an LTI feature on a sidewall of an intermediate lead are plating structures enhancing wettability for solder material and/or recesses. Reference is made to the above description of appropriate LTI features for the corner leads, which is also applicable for the intermediate leads.

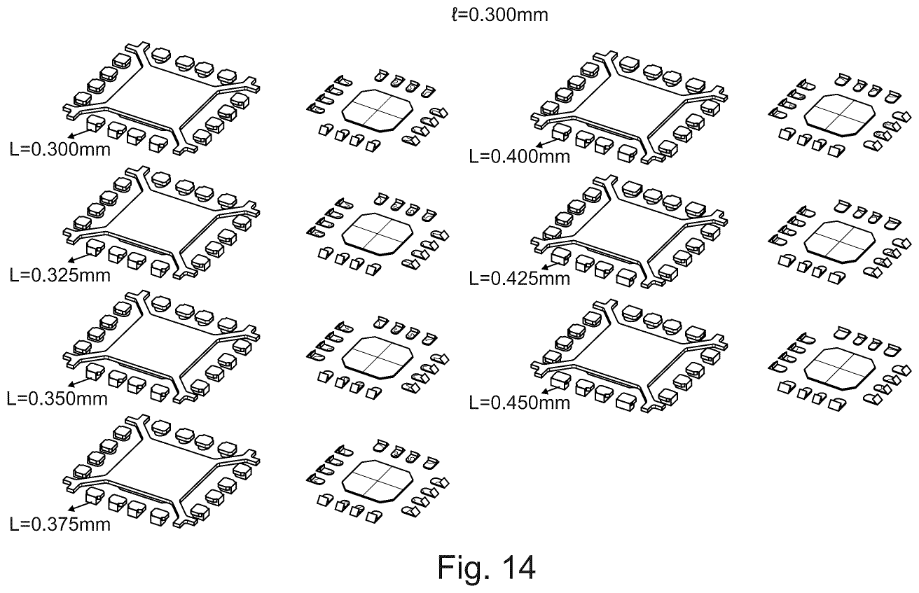

In an embodiment, said larger width of said corner leads is at least a factor of 1.1, for example at least a factor of 1.3, and preferably at least a factor of 1.5, of said smaller width of said intermediate leads. Simulation results according to FIG. 14 and Table 1 described below indicate that with the mentioned ratios, significant improvements may be achieved what concerns the TCoB behavior. By the mentioned selective increase of the corner lead width with respect to the intermediate lead width, a significant improvement of the robustness against thermal load may be achieved. In an embodiment, the mentioned factor may be not larger than 2 in order to avoid a change of pitch or the need to adapt a specification to significantly changed dimensions. However, in other embodiments, the factor may be even larger than 2.

In an embodiment, said larger width of said corner leads is at least 0.37 mm and said smaller width of said intermediate leads is not more than 0.33 mm. For example, the width of the corner leads may be at least 0.4 mm, whereas the width of the intermediate leads may be not larger than 0.3 mm. This may allow to produce miniature packages while simultaneously providing an efficient robustness against thermal load.

In an embodiment, the carrier comprises at least one anchoring extension being integrally formed with the component mounting structure and extending outwardly from said at least one corner of said component mounting structure. Such an anchoring extension may be an additional measure for improving performance of the package what concerns protection against thermal cycling caused failure. The anchoring extensions, for instance four anchoring extensions extending radially outwardly from each of four corners of a rectangular component mounting structure, may provide a powerful protection against thermal load. However, in other embodiments, only one, two, three or more than four anchoring extensions may be foreseen. To put it shortly, the anchoring extensions may be anchored inside encapsulant material (for instance mold compound) and may therefore counteract against mechanical load which may be caused for instance by a CTE (coefficient of thermal expansion) mismatch between a printed circuit board and a package. The at least one anchoring extension is optional. If present, the first failure may occur at the at least one anchoring extension which may be embodied as dummy tie bar, thereby preventing the functional corner leads and intermediate leads against early failure.

In an embodiment, the at least one anchoring extension may be provided with a lead tip inspection (LTI) feature. For example, such an LTI feature may be a recess in the respective anchoring extension and/or a plating structure on the respective anchoring extension (preferably a plating structure on a recess of the respective anchoring extension) for promoting wetting of a surface of the respective anchoring extension by molten solder. This may further improve the reliability of the package again second level solder fatigue failure.

In an embodiment, said leads extend around an entire perimeter of the component mounting structure, wherein said corner leads are a subgroup of said leads being located next to all four corners of said component mounting structure, and said intermediate leads being located along said edges of the component mounting structure and between corner leads. In such an embodiment, a rectangular component mounting structure may be fully circumferentially surrounded by leads, i.e., leads extending along each of four edges of the rectangular or substantially rectangular component mounting structure. In such a package design, the corner leads are usually the weak point of the system in terms of second level solder fatigue failure. However, when applying width extension selectively to the corner leads in combination with an LTI feature, the robustness of a corresponding package against second level solder fatigue failure may be significantly improved. At each of four corners of a rectangular component mounting structure, two corner leads may be provided facing two angled sidewalls close to a diagonal position of the rectangular component mounting structure, preferably closer to the diagonal position than all intermediate leads.

In an embodiment, the carrier is configured for use in a leadless package. In particular, the leads of such a carrier may be configured to meet the requirements of a leadless package, as described above.

For example, the carrier may be embodied as a leadframe structure. In the context of the present application, the term “leadframe” may particularly denote a sheet-like metallic structure which can be bent, punched and/or patterned so as to form leadframe bodies as mounting sections for mounting chips, and connection leads for electric connection of the package to an electronic environment. In an embodiment, the leadframe may be a metal plate (in particular made of copper) which may be patterned, for instance by stamping. Forming the carrier as a leadframe structure is a cost-efficient and mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

However, the carrier may also be a Direct Copper Bonding (DCB) substrate or a Direct Aluminium Bonding (DAB) substrate. Furthermore, the carrier may also be configured as Active Metal Brazing (AMB) substrate, or as Insulated Metal Substrate (IMS).

In an embodiment, the carrier comprises or consists of a patterned metal plate. For example, a metal plate may be provided which may for instance be made of copper or aluminum. By merely patterning such a plate, for instance by stamping, punching, coining, etching and/or routing, the arrangement of component mounting structure and adjacent leads may be obtained with low effort. At the same time, the electrically conductive properties of such a patterned metal plate may ensure that not only the leads, but also the component mounting structure may contribute to the electric connection inside of the package.

In an embodiment of the package, at least part of exterior sidewalls at least of the corner leads are exposed beyond the encapsulant. When the sidewalls of the corner leads are exposed beyond the encapsulant of a package, they can be covered with solder fillet during establishing a solder connection between package and a mounting base, for instance a printed circuit board. Such a solder fillet on a lead sidewall may significantly improve the mechanical stability of the package and of the electronic device and may function as a reliable protection against thermal load caused failure which may otherwise occur during thermal cycling.

In an embodiment, at least part of exterior sidewalls of the intermediate leads are exposed beyond the encapsulant. By also exposing sidewalls of the intermediate leads after encapsulation by an encapsulant, a lead tip inspection feature of such sidewalls may result in a coverage also of such sidewalls by a solder fillet. This may further increase the mechanical stability of the package and of the electronic device.

In an embodiment, at least part of bottom walls of the leads (more specifically on the corner leads and/or of the intermediate leads) are exposed beyond the encapsulant. Hence, also bottom walls of the corner leads may be exposed beyond the encapsulant so that a solder connection can be established between such bottom walls and pads of a mounting base. In addition, also bottom walls of the intermediate leads may be exposed beyond the encapsulant for establishing a mechanical and electrical connection between the package and the mounting base, preferably by soldering.

In an embodiment, the electronic device comprises a solder structure connecting the leads and/or the component mounting structure with the mounting base, in particular with electrically conductive pads thereof. For example, exposed electrically conductive pads of the mounting base (for instance of a PCB) may be solder-connected with exposed bottom walls of the corner leads and/or of the intermediate leads and/or of the component mounting structure. This may create a mechanical and/or electric connection in between. When providing a lead tip inspection feature (for instance by a plating structure and/or a surface-increasing measure such as formation of at least one recess), the molten solder material will wet corresponding surfaces of the leads. Particular solder fillet formation on exposed sidewalls of the corner leads and/or intermediate leads may additionally enhance the mechanical stability and the robustness against thermally caused failure.

In an embodiment, part of the solder structure covers at least part of exterior sidewalls at least of the corner leads, said at least part of exterior sidewalls being exposed beyond the encapsulant. Such a sidewall coverage by solder material may be the result of the LTI feature on the sidewall of the corner leads, and optionally also of the intermediate leads.

In an embodiment, the package is configured as power package. A power package may be a package comprising at least one power chip as encapsulated electronic component. Thus, the package may be configured as power module, for instance molded power module such as a semiconductor power package. For instance, an exemplary embodiment of the package may be an intelligent power module (IPM). Also a Smart IPM is possible (including a microcontroller). The package may also provide connectivity features, for instance WiFi, Bluetooth, etc. Another exemplary embodiment of the package is a dual inline package (DIP).

Correspondingly, the electronic component may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc. Advantages of exemplary embodiments concerning enhanced thermal reliability may be pronounced for power dies.

As substrate or wafer for the semiconductor chips, a semiconductor substrate, for example a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Leadless packages are attractive due to their relatively small size, low manufacturing effort and superior thermal and electrical performance. Especially for wide bandgap devices, leadless packages may be preferred for low inductance. An exposed pad may also help to improve electrical performance. However, leadless packages may have board-level concerns, for example in the solar application area. In particular, solder joint reliability under temperature cycling on board (TCoB) test may be a requirement. Therefore, improving the package board level robustness and maintaining small size and low manufacturing effort may be desired.

According to an exemplary embodiment, a (preferably metallic) carrier for a leadless package is provided, as well as said leadless package and an electronic device obtained by mounting such a leadless package on a mounting base (such as a PCB). The carrier comprises a component mounting structure (such as a die pad) for mounting an electronic component (such as a die) thereon. The carrier may further comprise a plurality of (preferably metallic) leads arranged around part of or even the entire component mounting structure. Corner leads (or corner pads) of said leads may be located closer to corners of said component mounting structure than intermediate leads (or intermediate pads) of said leads being located further away from the respective corner than said corner leads. In particular, corner leads may be closest to the corners, whereas intermediate leads may be remote from said corners or more remote from said corners than the corner leads. Said corner leads may have a larger width along a respective edge of the component mounting structure compared with a smaller width of said intermediate leads along a respective edge of the component mounting structure. In addition, said corner leads may comprise a lead tip inspection (LTI) feature. Advantageously, such a carrier architecture may provide a pronounced solder joint reliability under temperature cycling on board (TCoB) test. More specifically, it may be possible to obtain a significant improvement of the TCoB performance of a package (in particular a VQFN package (Very Thin Profile Quad Flat Non Leaded Package)) by implementing LTI features plus wider corner leads or corner pin pads. The combination of LTI and wider corner pin pads has turned out to significantly improve VQFN package board level robustness. In conclusion, simulations confirm that said improvement may be obtained by a combination of the mentioned two measures (i.e. spatially extended corner leads and an LTI feature thereof), which may bring outstanding results.

More specifically, an exemplary embodiment proposes to widen the corner leads or corner pin pads (for example from 0.3 mm to 0.4 mm), as it is believed that the corner pads are the most critical ones with respect to solder joint fatigue failure. Besides that, LTI features may be implemented for the corner leads and preferably also to the smaller intermediate leads. This may cause solder fillet formation on exposed side surfaces of peripheral leads. Without wishing to be bound to a specific theory, it is presently believed that taking these measures may strongly help to suppress undesired phenomena relating to coefficient of thermal expansion (CTE) mismatch between package material and mounting base material, i.e. for instance mismatch between package and PCB board. By doing this, simulations indicate that this will improve the TCoB performance to become much higher. This improvement is significant and is very easy to implement.

Thus, exemplary embodiments provide a low effort solution to provide a thermally highly robust package. This may be beneficial for many applications including in particular solar applications. In addition, by providing a leadless package, it may be possible to reduce the space consumption on a PCB board compared with leaded packages. Staying small but much more robust may thus be advantages of packages according to exemplary embodiments. In addition, an LTI feature at a corner lead may also help to control solder joint on a PCB board in an electronic device.

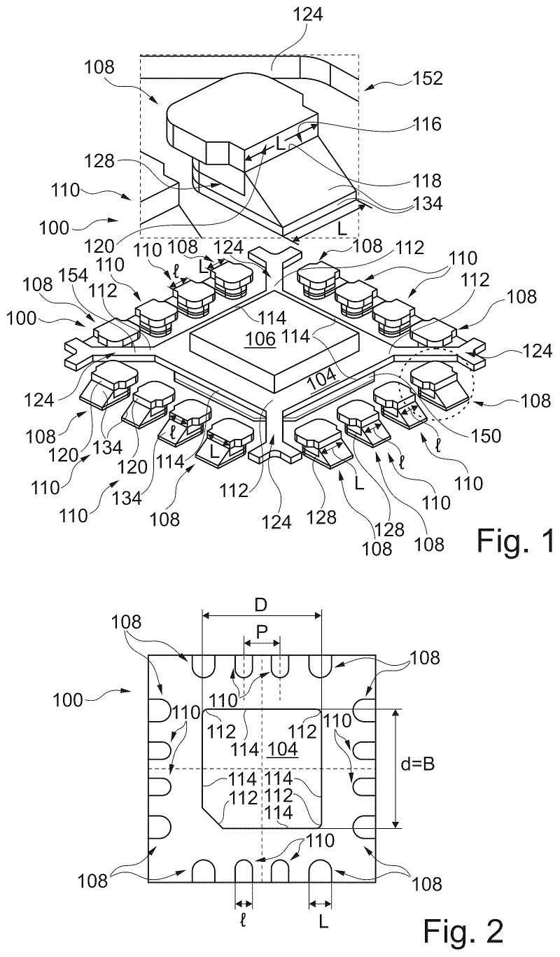

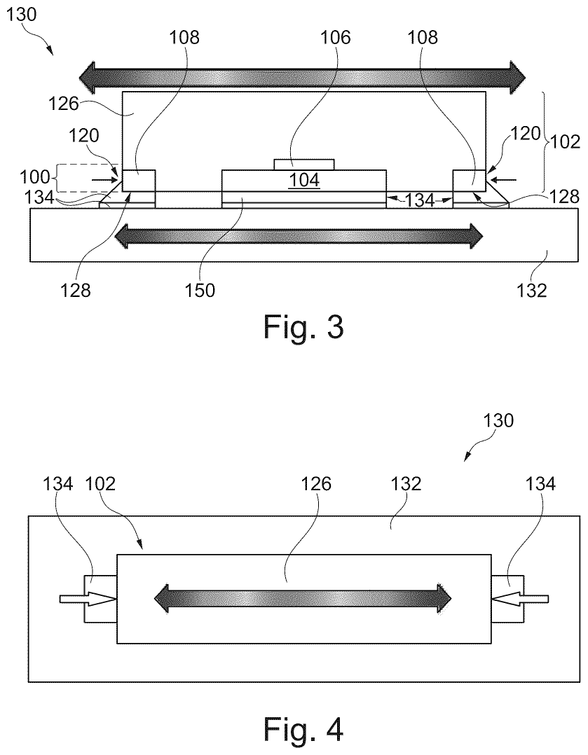

FIG. 1 illustrates different views of a carrier 100 for a leadless package (see reference sign 102 in FIG. 3) according to an exemplary embodiment.

The illustrated leadframe structure-type carrier 100 is configured to be used when forming a leadless package 102. The carrier 100 comprises a central component mounting structure 104 for mounting an electronic component 106 thereon. Furthermore, the carrier 100 comprises a plurality of leads 108, 110 arranged fully circumferentially around the perimeter of the component mounting structure 104. Each of corner leads 108 of said leads 108, 110 is located closer to the respectively next corner 112 of said component mounting structure 104 than intermediate leads 110 of said leads 108, 110. While FIG. 1 shows the corners 112 of the component mounting structure, corners of the entire package 102 may be located further outside, for instance at extrapolated intersections of the exterior surfaces of the leads 108, 110 of respectively two rows of leads 108, 110 (see the corners of the exterior rectangle of the illustration of FIG. 2). The intermediate leads 110 are located remote or further away from the next corner 112 than the respective corner leads 108. As shown, said corner leads 108 are a subgroup of said leads 108, 110 being located next to or closest to all four corners 112 of said component mounting structure 104. Correspondingly, said intermediate leads 110 are located along said edges 114 of the component mounting structure 104 and between corner leads 108. Referring to FIG. 1, four straight arrangements of leads 108, 110 are shown, wherein corner leads 108 are arranged at each end of said lead arrangements, whereas intermediate leads 110 are located in gaps between the outermost corner leads 108 of each lead arrangement.

While exemplary embodiments relate to a QFN-type package 102 having leads 108, 110 on all the four sides of the package 102, other embodiments cover a leadless package 102 only having leads 108, 110 on two adjacent sides or on two opposing sides, so that a smaller number of corner leads 108 may be present.

As shown, said corner leads 108 have a larger width L along a respective edge 114 of the component mounting structure 104 compared with a smaller width l of said intermediate leads 110 along a respective edge 114 of the component mounting structure 104. Said larger width L of said corner leads 108 may be preferably at least a factor of 1.3 of said smaller width l of said intermediate leads 110. In particular, said larger width L of said corner leads 108 may be at least 0.37 mm (for example 0.4 mm) and said smaller width l of said intermediate leads 110 may be not more than 0.33 mm (for example 0.3 mm).

Advantageously, each of the corner leads 108 and each of the intermediate leads 110 comprises a lead tip inspection (LTI) feature 116, as will be described below in further detail.

To put it shortly, the embodiment of FIG. 1 selectively enlarges the corner leads 108 or pads to strengthen a solder joint of the most critical connections. By adding LTI features 116 at leads 108, 110, the joint strength on sidewalls 120 of the leads 108, 110 may be further improved. A corresponding solder fillet formation (see solder structures 134 in FIG. 1) on the exposed side surface of peripheral leads 108, 110 helps to absorb CTE mismatch.

Furthermore, carrier 100 comprises comprising anchoring extensions 124, one at each corner 112. The anchoring extensions 124 are integrally formed with the component mounting structure 104 and extend outwardly from the corners 112 of said component mounting structure 104. Although not shown in FIG. 1, also each of the anchoring extensions 124 may have an LTI feature. The anchoring extensions 124, in particular when provided with an LTI feature, may also suppress second level solder fatigue failure.

More specifically, FIG. 1 shows carrier 100 of a leadframe type, for instance made of a metallic material such as copper or aluminum. In a bottom portion of FIG. 1, the component mounting structure 104 is shown which is here embodied as a die pad. As shown, the component mounting structure 104 has a substantially rectangular shape with four corners 112 and four edges 114. On a bottom main surface of the component mounting structure 104, a solder structure 150 is shown which can be made flowable for establishing a solder connection with a mounting base (see reference sign 132 in FIG. 3), for instance a printed circuit board (PCB). On a top main surface of the component mounting structure 104, a further electrically conductive connection medium may be formed, for instance additional solder material (not shown in FIG. 1), for creating a connection with an electronic component 106 mounted thereon. In the shown embodiment, the electronic component 106 may be a semiconductor chip, for example a semiconductor power chip.

Still referring to the bottom portion of FIG. 1, it can be seen that the plurality of leads 108, 110 are arranged around the entire perimeter of the component mounting structure 104, for instance at a common vertical level. In other words, the component mounting structure 104 can be coplanar with the leads 108, 110. Alternatively, they may be arranged in different planes.

As already mentioned, two different types of leads 108, 110 are foreseen: A first type of leads are the corner leads 108 which are located closest to the corners 112 of the component mounting structure 104. More specifically, two corner leads 108 are provided per corner 112. Consequently, two corner leads 108 are arranged along each edge 114 of the component mounting structure 104. A second type of leads are the intermediate leads 110 which have a larger distance from the respective corner 112 than the adjacent corner leads 108. Along each edge 114 of the component mounting structure 104, one or more (in the shown embodiment two) intermediate leads 110 are arranged between two assigned corner pads 108. Four straight rows of leads 108, 110 are provided along the four edges 114.

It is believed that the corner pads 108 are most critical what concerns failure in the event of excessive thermal load, as may occur for example during a thermal cycling test. More specifically, the structure shown on the bottom side of FIG. 1 can be encapsulated by an encapsulant (see reference sign 126 in FIG. 3) when forming a package 102 based on the carrier 100 of FIG. 1. When such a package 102 is soldered onto a mounting base 132 such as a PCB, two bodies 132, 102 are connected which may have very different coefficients of thermal expansion (CTE). This may lead to a CTE mismatch. In the event of thermal load, the thermal expansion of the mounting base 132 may be thus significantly different from that of elements of package 102. Consequently, high mechanical load may be exerted. Under undesired circumstances, this may lead to failure of the package 102 or the entire electronic device 130.

Simulations indicate that the particularly critical corner leads 108 may be rendered significantly more robust against second level solder fatigue failure when taking two measures in combination. These measures will be explained in the following based on detail 152 on the top side of FIG. 1 showing a corner lead 108 in further detail. The first measure is that an increase of the width L of an exterior sidewall 120 of the corner leads 108 along an extension of the assigned edge 114 of the component mounting structure 104 compared to the smaller width l of an exterior sidewall of the intermediate leads 110 along an extension of the assigned edge 114 of the component mounting structure 104 may increase robustness against second level solder fatigue failure. Thus, the first measure is to provide a larger width L of the corner leads 108 compared to a larger width l of the intermediate leads 110. For example, a proper selection is L=0.4 mm and 1=0.3 mm. Of course, the exact values of L, 1 may depend on a certain application and will be selected appropriately by a person skilled in the art.

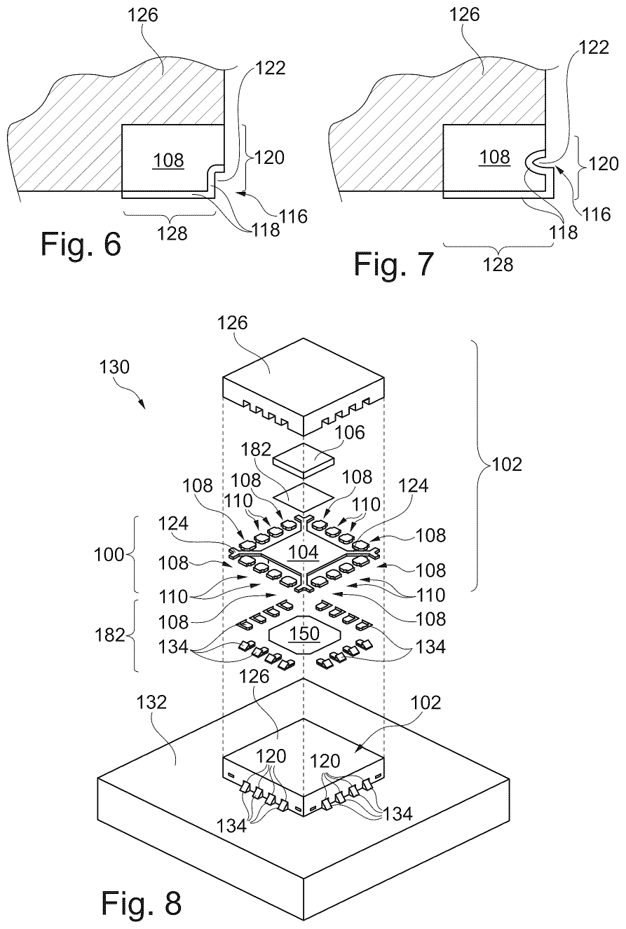

The second feature significantly improving robustness against second level solder fatigue failure is to provide a lead tip inspection (LTI) feature 116 at a vertical sidewall 120 of the respective corner lead 108, and preferably also at a vertical sidewall of the respective intermediate lead 110. In the shown embodiment, formation of the lead tip inspection feature 116 comprises the provision of a plating structure 118 (better visible in FIG. 6 or FIG. 7) on the sidewall 120. As shown, the plating structure 118 may also extend to a bottom wall 128 of the respective lead 180, 110. The material of the plating structure 118 is selected for promoting wettability of sidewalls 120 by solder material of solder structure 134 thereon. An appropriate material for such a plating structure is for instance tin or an alloy comprising tin. In addition, formation of LTI feature 116 may comprise forming one or more recesses 122 in sidewall 120 (not shown in FIG. 1), see for instance FIG. 6 or FIG. 7.

It has been surprisingly found that the combination of these two measures, i.e. selectively extending the width of the corner leads 108 and providing the exterior sidewall 120 of the corner leads 108 (and optionally also of the intermediate leads 110) with a lead tip inspection feature 116, may lead to an enormous improvement of the reliability against second level solder fatigue failure. The presence of the LTI feature 116 will lead to a solder fillet (see solder structure 134 in FIG. 1) covering at least parts of the sidewalls 120 of the leads 108, 110, which will provide an anchoring effect and thereby a protection against second level solder fatigue failure. At the same time, the increase of the width L in comparison with the other width l further enhances this effect. It has been surprisingly found that in particular the combination of these two measures provides a synergy in terms of improvement of the robustness against second level solder fatigue failure.

As shown as well in FIG. 1 are the already mentioned anchoring extensions 124 extending radially outwardly from each of the four corners 112 of the component mounting structure 104. These anchoring structures 124 have an oblong leg section 154 and a bifurcated end section 156. This geometry provides additionally an improvement in terms of robustness against second level solder fatigue failure.

FIG. 2 illustrates a plan view of a carrier 100 for a leadless package 102 according to an exemplary embodiment.

For the etched leadframe-type carrier 100, no additional process or effort is needed to widen corner leads 108 or corner pin pads. Substantially the same manufacturing process as for a conventional leadframe may be carried out, only the dimensions need to be adapted to ensure enough space for the wider corner leads 108 or corner pads.

A horizontal width D and a vertical width d of the component mounting structure 104 are shown as well. Furthermore, a pitch P between adjacent intermediate leads 110 is shown as well. Furthermore, a distance B between centers of corner pads 108 relating to the same edge 114 of the component mounting structure 104 are shown as well. In the shown embodiment, d=B. As can be taken from FIG. 2, the design of the leadframe type carrier 100 has only been adapted in a minor way for achieving the mentioned effects.

FIG. 3 illustrates a cross-sectional view of an electronic device 130 according to an exemplary embodiment. FIG. 4 illustrates a plan view of the electronic device 130 according to FIG. 3.

The illustrated electronic device 130 comprises a mounting base 132, for example a printed circuit board (PCB) or an interposer. A leadless package 102 is mounted on the mounting base 132. A solder structure 134 is provided for connecting the corner leads 108 and the intermediate leads 110 (not shown) and the component mounting structure 104 on the one hand with metallic pads (not shown) of the mounting base 132. Advantageously, part of the solder structure 134 covers part of exterior sidewalls 120 of the corner leads 108 and of the intermediate leads 110 (see arrows in FIG. 3). Said part of exterior sidewalls 120 are exposed beyond the encapsulant 126.

The leadless package 102 comprises a carrier 100, which may be configured for example as shown in FIG. 1. An electronic component 106, such as a power semiconductor chip, may be mounted on the component mounting structure 104. An encapsulant 126, for example a mold compound, may encapsulate the electronic component 106, part of the component mounting structure 104 and part of the leads 108, 110. As shown, part of exterior sidewalls 120 of the corner leads 108 (and of the intermediate leads 110, not shown in FIG. 3 and FIG. 4) are exposed beyond the encapsulant 126. Also bottom walls 128 of the leads 108, 110 are exposed beyond the encapsulant 126 for being connected with the mounting base 132 by the solder structure 134.

Without LTI features (see reference signs 116 in FIG. 6 and FIG. 7) provided at sidewalls 120 of leads 108, 110, the package 102 could execute a free expansion due to CTE mismatch between package 102 and PCB-type mounting base 132. Solder joints will then suffer significantly from fatigue shear loading during TCoB.

Without wishing to be bound to a specific theory, it is presently believed that by providing LTI features 116 at sidewalls 120 of the leads 108, 110, the package expansion freedom may be reduced, so that it may be possible to reduce shear loading on an interface between leads 108, 110 and solder structures 134. In addition, it has been found that wider corner leads 108 or corner pins may offer much stronger support against package expansion. Thus, specifically the combination of LTI features 116 (as shown in FIG. 6 or FIG. 7) and wider corner leads 108 (as shown in FIG. 1) may increase solder reliability during TCoB testing.

The cross-sectional view of the electronic device 130 of FIG. 3 shows package 102 mounted by a solder connection on PCB-type mounting base 132. FIG. 3 also shows solder structures 134 between pads of mounting base 132 and the exposed leads 108 (and 110) as well as the exposed component mounting structure 104 of package 102.

Due to different materials, the coefficient of thermal expansion of the mounting base 132 may vary significantly from the coefficient of thermal expansion of the package 102. Consequently, different thermal expansions may occur during a thermal cycling process which may lead to thermal load. However, by the combination of the selectively elongated corner leads 108 and the lead tip inspection feature 116 on their sidewalls 120 leading to a solder fillet of solder structure 134, the robustness against second level solder fatigue failure may be significantly improved.

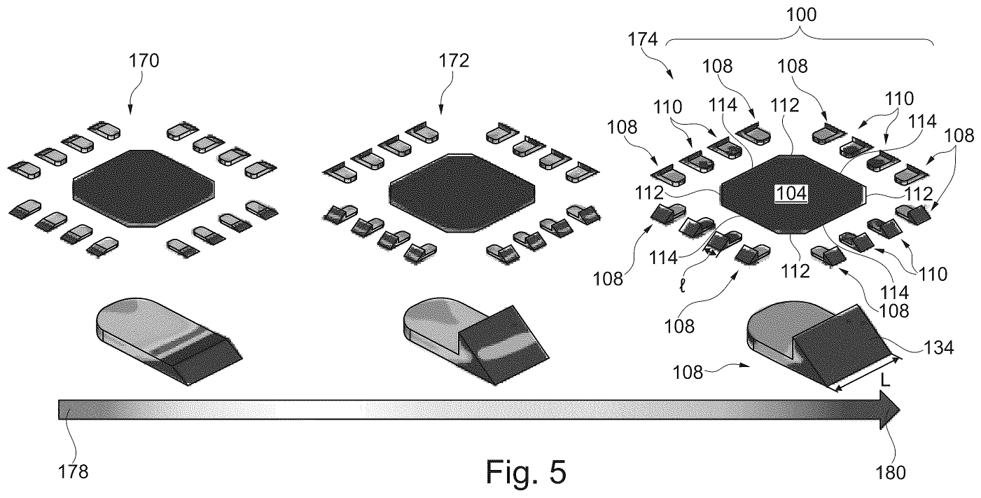

FIG. 5 illustrates a result of a simulation showing an improved second level solder joint thermal cycle on board (TCoB) test performance of a leadless package 102 according to an exemplary embodiment compared with other approaches. FIG. 5 shows a simulation result of an ordinary design of corner pads (see reference sign 170) without LTI feature and with L=1. As shown by reference sign 172, an improvement may be achieved by a lead tip inspection feature of the corner leads and also of the intermediate leads, wherein L=1 is maintained. As shown by reference sign 174, an enormous improvement may be achieved by combining the provision of a lead tip inspection feature 116 and the selective elongation of the width of the corner leads 108, i.e. L>1. This can be derived from the thermal load obtained by simulation, the result of which being shown in FIG. 5. High load is indicated by reference sign 178, whereas low load is indicated by reference sign 180.

More specifically, FIG. 5 relates to a TCoB simulation of the illustrated package type. For example, such a package may be used in solar micro inverters, where TCoB performance needs to be assessed. Simulations have been performed to estimate its TCoB solder joint failure risk based on a TCoB prediction life model. The simulation is started with a stress free temperature of 25° C. Three cycles of simulation have been carried out from −40° C. to +85° C. This corresponds to 1 hour for each thermal cycling test. FIG. 5 shows simulation results concerning solder joint damage evaluation, more specifically a solder damage distribution under fatigue loading.

The solder joint damage parameter creep strain energy density distribution after three cycling cycles is shown. Corner solder joint is identified as critical what concerns high failure risk. Based on a prediction life model, the solder joint first failure of the package may occur around 3000 cycles (see reference sign 170). By an LTI feature, critical solder joint damage may become lower (see reference sign 172). The predicted first failure occurs only after 6166 cycles under −40° C./+85° C. TCoB conditions. With the described LTI design, solder joint reliability is higher than those without LTI design. A wider corner lead-pin with LTI shows by far the highest solder joint reliability (see reference sign 174). The simulation indicates that a wider corner lead-pin with 50% LTI sidewall coverage may reach the requirement that the first failure does not occur before 10,000 cycles.

Hence, according to the simulation results, by the combination of LTI and wider corner pin pads, the TCoB of a VQFN package can be improved significantly without significant increase of effort.

FIG. 6 illustrates a cross-sectional view of part of a leadless package 102 according to an exemplary embodiment.

According to FIG. 6, said lead tip inspection feature 116 comprises a recess 122 formed in part of a respective sidewall 120 of a respective corner lead 108. As shown in FIG. 6, said recess 122 is formed in a corner region of the respective corner lead 108, which corner region includes a bottom portion of the sidewall 120 and a connected portion of a bottom wall 128 of the respective corner lead 108.

As shown, said lead tip inspection feature 116 comprises, in addition to recess 122, a plating structure 118 configured for being wettable by a solder structure 134 and being formed on part of a respective sidewall 120 of the shown corner lead 108. In addition, a further plating structure 118 configured for being wettable by a solder structure 134 is formed on a bottom wall 128 of the shown corner lead 108.

In particular, the illustrated embodiment shows an LTI and widened corner lead 108 being very easy to implement. There are several ways to enable LTI for package side wall wettability. Is the illustrated embodiment, a step-cut method can be used to enable LTI for the corresponding package 102.

Thus, FIG. 6 shows corner lead 108 having sidewall 120 and bottom wall 128 both being exposed beyond an encapsulant 126, such as a mold compound. Recess 122 formed in the corner region of the encapsulant-exposed corner of the corner lead 108 functions as a lead tip inspection feature improving the second level solder joint thermal cycle on board (TCoB) test performance. The lead tip inspection feature 116 provided by the recess 122 in the corner region may be further enhanced by covering the recess 122 by plating structure 118 which promotes wettability of solder material 134 (not shown in FIG. 6). In addition, also the bottom wall 128 of the corner lead 108 is covered by plating structure 118 which improves a reliability of the solder connection between corner lead 108 and an exposed pad of a mounting base 132.

FIG. 7 illustrates a cross-sectional view of part of a leadless package 102 according to another exemplary embodiment.

According to the embodiment of FIG. 7, the recess 122 is formed in a central portion of the sidewall 120 of the corner lead 108, i.e. apart from and above its corner region.

FIG. 7 shows a similar view as FIG. 6, but provides a recess 122 in a central portion of the vertical sidewall 120 of the exposed corner lead 108. When covered by a plating structure 118, such a central recess 122 may function as a powerful LTI feature 116 improving the thermal reliability of the package 102 and in particular of the corner lead 108 thereof.

FIG. 8 illustrates different views of an electronic device 130 according to an exemplary embodiment. More specifically, FIG. 8 shows an exploded view and an assembled view of electronic device 130.

The electronic device 130 comprises a PCB-type mounting base 132 on which a package 102 is assembled. As seen in a bottom portion of FIG. 8, sidewalls 120 of leads 108, 110 are partially exposed and are partially covered by a solder fillet of solder structure 134. Thus, a high mechanical robustness and high robustness against second level solder fatigue failure may be achieved. The exploded view of the constituents of the package 102 show a mold compound forming encapsulant 126 on the top side, and an electronic component 106 in the form of a semiconductor die below. By a solder structure 182, the electronic component 106 may be solder-connected on component mounting structure 104 of the carrier 100 shown beneath. The corner leads 108 of the carrier 102 may be provided by an LTI feature 116 and may be selectively elongated in comparison with the intermediate leads 110 in between. FIG. 8 also shows various elements of solder structures 134, 150 which are used for connecting the leads 108, 110 and the component mounting structure 104 with pads (not shown) of the mounting base 132.

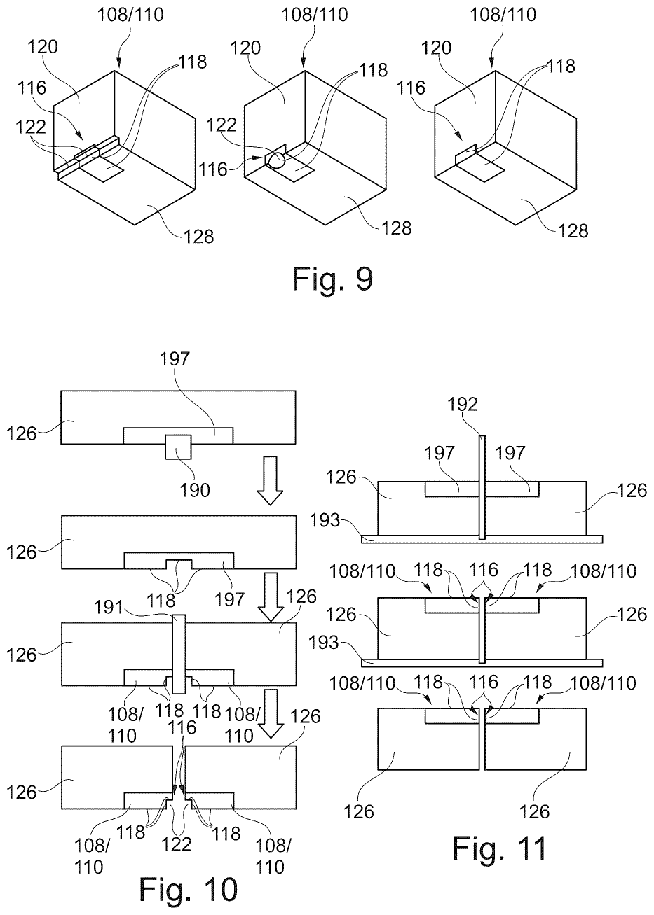

FIG. 9 illustrates three-dimensional views of leads 108, 110 and showing lead tip inspection features 116 according to exemplary embodiments.

On the left-hand side, FIG. 9 shows an embodiment of a lead tip inspection feature 116 in form of a step cut at a lead corner between a sidewall 120 and a bottom wall 128 of the lead 108, 110. In this embodiment, the step cut is formed as a recess 122 extending along an entire lead edge between sidewall 120 and bottom wall 128. In addition, a portion of the step cut and a portion of the bottom wall 128 are covered with a plating structure 118.

In a central scheme, FIG. 9 shows an embodiment of a lead tip inspection feature 116 in form of a dimple-type recess 122 at a lead corner between a sidewall 120 and a bottom wall 122 of the lead 108, 110. In addition, the dimple and a portion of the bottom wall 128 are covered with a plating structure 118.

On the right-hand side, FIG. 9 shows an embodiment of a lead tip inspection feature 116 in form of a plating structure 118 on a sidewall 120 and on part of a bottom wall 122 of the lead 108, 110. Hence, no recess 122 is provided in this embodiment. The right-hand side of FIG. 9 may relate to full plating in which the full sidewall of the metal lead 108, 110 may be plated.

FIG. 10 illustrates different views of a process of manufacturing leads 108, 110 with lead tip inspection feature 116 according to an exemplary embodiment.

As shown in a first scheme, a leadframe 197 constituting a pre-form of leads 108, 110 is encapsulated in an encapsulant 126 and is subjected to a sawing process by a first blade 190. First blade 190 saws up to part (for example half) of the leadframe depth.

As shown in a second scheme, deflashing and electroplating on an exposed copper surface is executed for forming plating structure 118.

As shown in a third scheme, a second sawing process is then executed with a second blade 191 being narrower than the wider first blade 190.

As shown in a fourth scheme, leads 108, 110 are obtained with a plated step constituting a lead tip inspection feature 116.

FIG. 11 illustrates different views of a process of manufacturing leads 108, 110 with lead tip inspection feature 116 according to another exemplary embodiment.

As shown in a first scheme, a leadframe 197 constituting a pre-form of leads 108, 110 is encapsulated in an encapsulant 126 arranged on a dicing tape 193 and is subjected to a sawing process by a blade 192 for separation into different pieces.

As shown in a second scheme, the encapsulated leads 108, 110 are subjected to chemical roughening and plating (for instance by electroless nickel immersion gold, ENIG) for forming plating structure 118.

As shown in a third scheme, dicing tape 193 may be removed, and the encapsulated leads 108, 110 with plating structure 118 are obtained constituting a lead tip inspection feature 116 on a sidewall 120.

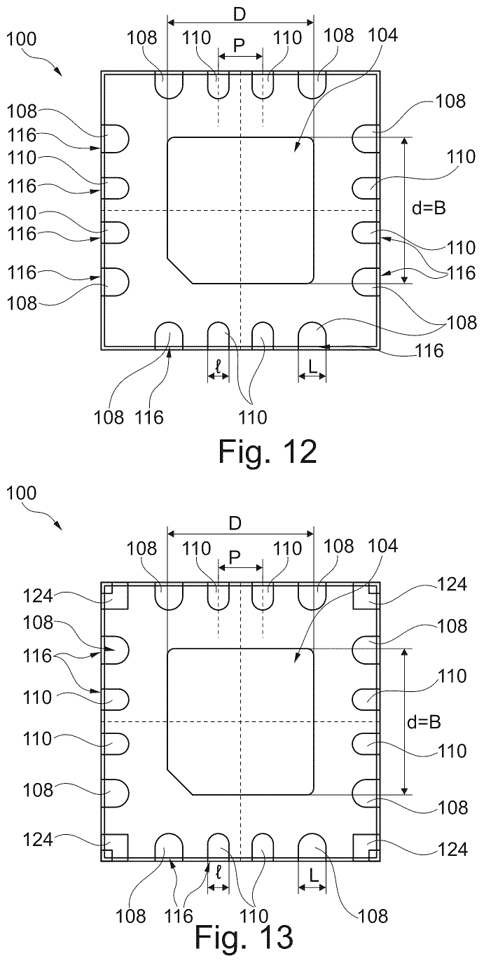

FIG. 12 illustrates a plan view of a carrier 100 with lead tip inspection feature 116 for a package 102 according to an exemplary embodiment. In addition to the embodiment of FIG. 2, FIG. 12 also shows a lead tip inspection feature 116, for instance comprising a stepped corner of the respective leads 108, 110 (preferably in combination with a plating structure 118, not visible in FIG. 12).

FIG. 13 illustrates a plan view of a carrier 100 with lead tip inspection feature 116 for a package 102 according to another exemplary embodiment. In addition to the embodiment of FIG. 12, FIG. 13 also shows anchoring extensions 124.

FIG. 14 illustrates a result of a simulation showing an improved second level solder joint thermal cycle on board (TCoB) test performance of packages 100 according to exemplary embodiments.

In the results of the illustrated simulation (wherein reference signs are omitted im FIG. 14 for the sake of simplicity), the width, l, of the intermediate leads 110 is kept at of 0.3 mm, whereas the width, L, of corner leads 108 are changed over a range from 0.3 mm to 0.45 mm. The following Table 1 shows simulation results:

TABLE 1
Second level solder joint thermal cycle
on board (TCoB) test performance

| Width of corner leads | Number of cycles | Relative improvement |
|---|---|---|
| in mm (intermediate | of predicted | of TCoB (reference: |
| leads width 0.3 mm) | first failure | 100%) |
| 0.300 | 6166 | 100.0% |
| 0.325 | 7223 | 117.1% |
| 0.350 | 8291 | 134.5% |
| 0.375 | 9609 | 155.8% |
| (factor: 1.25) | | |
| 0.400 | 10770 | 174.7% |
| (factor 1.33) | | |
| 0.425 | 12731 | 206.5% |
| 0.450 | 14434 | 234.1% |
| (factor 1.5) | | |

with increasing width of corner leads and constant width of intermediate leads

As can be taken from the simulation results of Table 1, a significant improvement can be achieved when increasing the width of the corner leads while keeping the width of the intermediate leads constant. The larger the width of the corner leads (first column), the larger is the number of cycles of predicted first failure (second column), and the larger is the TCoB performance in percent (third column) compared with the reference L=1=0.3 mm. According to Table 1, the corner leads width to intermediate lead width ratio or factor changes from 1 to 1.5. Table 1 shows a continuous improvement in term of percentage of TCoB. For instance, a width 0.375 mm of the corner leads may improve the TCoB by about 55% (i.e. 155.8%-100%), etc.

However, it should be said that Table 1 is just one simulation result. In practical manufacture, differences may occur. Hence, Table 1 should be interpreted as a result of a simulation only. Further, this simulation is just one embodiment for showing the effect of the combination of the above described two measures, and should not be used to limit the interpretation of embodiments to specific numbers.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A carrier for a leadless package, wherein the carrier comprises:
a component mounting structure for mounting an electronic component thereon; and
a plurality of leads arranged around at least part of the component mounting structure;
wherein corner leads of said leads are located closer to at least one corner of said component mounting structure than intermediate leads of said leads located farther away from said at least one corner than said corner leads;
wherein an exposed surface area of a sidewall of said corner leads have a larger width along a respective edge of the component mounting structure compared with a smaller width of an exposed surface area of a sidewall of said intermediate leads; and
wherein at least the exposed surface area of the sidewall and said corner leads comprise a lead tip inspection feature.

2. The carrier according to claim 1, wherein said lead tip inspection feature comprises a plating structure configured for being wettable by a solder structure and being formed on at least part of a respective sidewall of a respective one of at least said corner leads.

3. The carrier according to claim 1, wherein said lead tip inspection feature comprises a recess, said recess being formed in at least part of a respective sidewall of a respective one of at least said corner leads.

4. The carrier according to claim 3, wherein said recess is formed in a corner region of the respective corner lead, which corner region includes a bottom portion of the sidewall and a connected portion of a bottom wall of the respective corner lead.

5. The carrier according to claim 3, wherein said recess is formed in a central portion of the sidewall of the respective corner lead, as a dimple or a step.

6. The carrier according to claim 1, wherein each of the leads comprises a plating structure configured for being wettable by a solder structure and being formed on a bottom wall of the respective lead.

7. The carrier according to claim 1, wherein the intermediate leads comprise a lead tip inspection feature.

8. The carrier according to claim 1, wherein said larger width of the exposed surface area of the sidewall of said corner leads is at least a factor of 1.1, of said smaller width of the exposed surface area of the sidewall of said intermediate leads.

9. The carrier according to claim 1, wherein said larger width of the exposed surface area of the sidewall of said corner leads is at least 0.37 mm and said smaller width of the exposed surface area of the sidewall of said intermediate leads is not more than 0.33 mm.

10. The carrier according to claim 1, comprising at least one anchoring extension being integrally formed with the component mounting structure and extending outwardly from said at least one corner of said component mounting structure.

11. The carrier according to claim 10, wherein the at least one anchoring extension is provided with a lead tip inspection feature.

12. The carrier according to claim 1,
wherein said leads extend around an entire perimeter of the component mounting structure;
wherein said corner leads are a subgroup of said leads being located next to all four corners of said component mounting structure, and said intermediate leads being located along said edges of the component mounting structure and between corner leads.

13. The carrier according to claim 1, wherein the carrier is configured for use in a leadless package.

14. A leadless package, which comprises:
a carrier according to claim 1;
an electronic component mounted on the component mounting structure; and
an encapsulant encapsulating at least part of the electronic component, at least part of the component mounting structure and only part of the leads.

15. The package according to claim 14, wherein at least part of exterior sidewalls at least of the corner leads are exposed beyond the encapsulant.

16. The package according to claim 14, wherein at least part of the exposed, exterior sidewalls of the intermediate leads are exposed beyond the encapsulant.

17. The package according to claim 14, comprising at least one of the following features:
wherein at least part of bottom walls of the leads are exposed beyond the encapsulant;
wherein the electronic component is a semiconductor power chip;
wherein the package is a power package.

18. An electronic device, comprising:
a mounting base; and
a package according to claim 14 mounted on the mounting base.

19. The electronic device according to claim 18, comprising a solder structure connecting the leads and/or the component mounting structure with the mounting base.

20. The electronic device according to claim 19, wherein part of the solder structure covers at least part of the exposed, exterior sidewalls at least of the corner leads, said at least part of the exposed, exterior sidewalls being exposed beyond the encapsulant.
